(19) United States
(12) Patent Application Publication
(10) Pub. No.: US 2015/0014824 A1
(43) Pub. Date: Jan. 15, 2015

(54) METHOD FOR FABRICATING A SEMICONDUCTOR DEVICE

(71) Applicant: Oleg Kononchuk, Grenoble (FR)

(72) Inventor: Oleg Kononchuk, Grenoble (FR)

(73) Assignee: SOITEC, Bernin (FR)

(21) Appl. No.: 14/364,900

(22) PCT Filed: Dec. 15, 2011
(86) PCT No.: PCT/EP2011/006348

§ 371 Date: Sep. 10, 2014

(51) Int. Cl. H01L 21/3105; H01L 29/34

(52) U.S. Cl. CPC H01L 21/31053; H01L 29/34
USPC 257/647; 438/476

(57) ABSTRACT

The present invention relates to a method for fabricating a substrate for a semiconductor device comprising an interface region between a first layer and a second layer having different electrical properties and an exposed surface, wherein at least the second layer includes defects and/or dislocations, the method comprising the steps of: a) removing material at one or more locations of the defects and/or dislocations, thereby forming pits, wherein the pits intersect the interface region, and b) passivating the pits. The invention also relates to a corresponding semiconductor device structure.

### CROSS-REFERENCE TO RELATED APPLICATIONS

This application is a national phase entry under 35 U.S.C. §371 of International Patent Application PCT/EP2011/006348, filed Dec. 15, 2011, designating the United States of America and published in English as International Patent Publication WO2012/089314 A2 on Jul. 5, 2012, the disclosure of which is hereby incorporated herein in its entirety by this reference.

### TECHNICAL FIELD

The present invention relates to a substrate for a semiconductor device and a method for fabricating the substrate for the semiconductor device. In particular, the invention relates to the substrate for a semiconductor device and the method for fabricating a substrate for a semiconductor device for improving the performance of semiconductor devices, in particular, power semiconductor devices and/or photovoltaic devices.

### BACKGROUND

Power semiconductor devices are semiconductor devices used as, for example, switches or rectifiers in power electronic circuits, integrated circuits and the likes. Photovoltaic devices comprise semiconductor devices configured to transform electromagnetic radiation into electric energy. Typically, a power semiconductor device or a photovoltaic device structure employs a pn-junction and the electric field intensity within the device is maximized at an interface region, such as the internal metallurgic junction, between the p-type material and the n-type material of the device. Power semiconductor devices may, e.g., include a GaN based Schottky diode. Photovoltaic devices may include, for example, a solar cell.

Defects and/or dislocations in a semiconductor material affect the quality of a surface layer grown over the semiconductor material. In addition, additional layers provided over the surface layer, e.g., by deposition, can also be affected by the defects and/or dislocations. In a power semiconductor device or a photovoltaic device defects and/or dislocations like, for example, threading dislocations present in the interior of a semiconductor layer degrade the device's performance, for example, by affecting the breakdown voltage of the device or by affecting the energy conversion, respectively, Poor breakdown voltage in the power semiconductor device can prevent high performance at high voltages.

To deal with defects, expensive and massive starting materials like a massive GaN wafer with low defect density, needs to be used. To reduce the influence of defects in multilayer structures, prior art document WO 2008/141324 A2 proposes a method wherein surface defects present in one epitaxial layer are capped with a masking material before a following layer is grown over the first capped layer with the caps. Another method is disclosed in US 2004/0067648 A1. During the growth of one layer a plurality of etch pits are formed on each end of the dislocations. Then, an amorphous coat film is provided on the inner surface of each etch pits to avoid the growth of crystal thereon. Subsequently, the growth of the same layer is continued and the dislocation density above the regions of the amorphous coat films is depicted as being reduced.

### BRIEF SUMMARY

It is an object of the present invention to provide a substrate for a semiconductor device and a method for fabricating the substrate for the semiconductor device, which can be based on the use of thin films while at the same time an improved device performance is obtained.

The object of the invention is achieved with a method for fabricating a substrate for semiconductor device comprising an interface region between a first layer and a second layer having different electrical properties and an exposed surface, wherein at least the second layer includes defects and/or dislocations, the method comprises the steps of a) removing material at one or more locations of the defects and/or dislocations, thereby forming pits, wherein the pits intersect the interface region, and b) passivating the pits.

By removing material at one or more locations of the defects and/or dislocations and passivating these regions, the regions in the vicinity of the defects and/or dislocations can also be passivated, thereby an improved performance of a power device and/or photovoltaic device can be realized.

Preferably, the passivating step can include at least partially filling the pits with a dielectric material. By filling the pits with a dielectric material, an improved performance of a power device and/or photovoltaic device can be realized due to improved and efficient passivation.

Preferably, the first layer can comprise a semiconductor material including a first impurity and the second layer can comprise a semiconductor material including a second impurity different from the first impurity. The first and second impurity may be dopant elements as p-type or n-type dopings. In particular, the interface region can be a metallurgic junction, wherein the metallurgic junction is a junction formed by adjoining the first layer comprising the semiconductor material including the first impurity and the second layer comprising the semiconductor material including the second impurity. For example, in a diode having a pn-junction, a line dividing a p-type semiconductor material and an n-type semiconductor material is the interface region or the metallurgic junction. By having the regions with removed material intersecting the interface region, defects and/or dislocations are removed from the area with the highest electric field.

Preferably, the step of the removing material can comprise a step of etching the exposed surface preferentially at one or more locations of the defects such that one or more pits are formed, or existing pits are further exposed, at the locations of surface defects. Herein, the term “defect” is used to refer to any threading dislocations, loop dislocations, stacking faults and grain boundaries in the material. The pits are preferably sufficiently large so that the disordered material is removed from the surface such that pits intercept defects and/or dislocations present in the interior of the semiconductor layers through the interface region. Such an etching allows removing selectively or preferentially the regions having the defects and/or dislocations leaving out the non-defective regions.

Preferably, the dielectric material can be chosen from any one of silicon oxide, silicon nitride and mixtures thereof. Dielectric material chosen from the above materials helps to suppress the defects and/or dislocations in layers subsequently provided over the dielectric material.

Preferably, the dielectric material can completely fill the regions from which the material is removed in step a). By completely filling the etched regions, an essentially defect-free surface layer can be obtained. The filling can be performed by depositing, or by growing, or by otherwise placing dielectric material on the surface of the layer so as to occlude the surface openings of the pits and cover any exposed portions of the walls of the pits, but such that intact portions of the surface away from the pits are exposed.

Preferably, the method can comprise a step of polishing the surface of the semiconductor device after step b), wherein the surface of the semiconductor device structure is polished until the surface of the second layer is recovered. After filling the etched regions with the dielectric material, the surface of the substrate for semiconductor device can be polished such that the surface is an essentially defect and/or dislocation free surface. By doing so, the surface can be of high quality and ready for further fabrication steps comprising providing, e.g., by deposition or growth of additional layers over the substrate for semiconductor device.

Preferably, the substrate for semiconductor device can comprise a transistor, diode or a photovoltaic device, such as a solar cell, such that a semiconductor device with fewer defects and/or dislocations can be realized and Schottky layers can be formed over the transistor, diode or the solar cell.

The object of the invention is also achieved by a substrate for a semiconductor device comprises an interface region between a first layer and a second layer having different properties, wherein pits extend through the second layer and at least partially into the first layer so as to cross the interface region, wherein the pits are at least partially filled with a dielectric material. With this semiconductor device structure, thin film starting materials, e.g., GaN thin films can be used and still high breakdown voltages can be obtained.

Preferably, the first layer can comprise a semiconductor material including a first impurity and the second layer comprises a semiconductor material including a second impurity different to the first impurity. The first and second impurity may be dopant elements as p-type or n-type dopings. In particular, the interface region can be a metallurgic junction, wherein the metallurgic junction is a junction fainted by adjoining the first layer comprising the semiconductor material including the first impurity and the second layer comprising the semiconductor material including the second impurity. For example, in a diode having a pn-junction, a line dividing a p-type semiconductor material and an n-type semiconductor material is the interface region or the metallurgic junction.

Preferably, the semiconductor material can be an III/N material, the first impurity is silicon and the second impurity is magnesium.

Preferably, the dielectric material can be chosen from any one of silicon oxide, silicon nitride and mixtures thereof. Dielectric material chosen from the above materials helps to suppress the defects and/or dislocations in layers subsequently provided over the dielectric material.

Preferably, the dielectric material can completely fill the one or more regions. By completely filling the etched regions, a defect-free surface layer can be obtained.

According to a preferred embodiment, the pits filled with dielectric material can be arranged on top of dislocations and/or defects in the first layer. Therefore, the presence of such defects and/or dislocations in the transition area between first and second layer can be prevented.

The object of the invention is also achieved by a power semiconductor device such as a transistor, a diode or a photovoltaic device such as solar cell including the substrate of the present invention such that a semiconductor device with fewer defects and/or dislocations can be realized.

### BRIEF DESCRIPTION OF THE DRAWINGS

Specific embodiments of the present invention will become more apparent from the present description with reference to the accompanying drawings, wherein:

FIG. 1a illustrates a cross-section of a starting substrate used for, for example, fabricating a substrate for semiconductor device structure, according to an embodiment of the present invention,

FIG. 1b illustrates a step of removing materials from an exposed area of the substrate of the semiconductor device as illustrated in FIG. 1a,

FIG. 1c illustrates a step of filling regions, from where materials were removed, with a dielectric material, and

FIG. 1d illustrates a step of polishing the exposed surface of the substrate of the semiconductor device as illustrated in FIG. 1c.

FIGS. 1a-1d illustrate a method for fabricating a substrate for a semiconductor device, according to the invention.

FIG. 1a illustrates a cross-sectional view of a pn-junction region of a semiconductor device structure 1, according to an embodiment of the present invention. The semiconductor device structure 1 comprises a substrate 3, a first semiconductor layer 5 provided over the substrate 3, a second semiconductor layer 7 provided over the first semiconductor layer 5 and an interface region 9 between the first semiconductor layer 5 and the second semiconductor layer 7. In a variant, the semiconductor device structure 1 can comprise more than two semiconductor layers over the substrate 3.

### DETAILED DESCRIPTION

The substrate 3 serves as a starting material for the growth of the first and second layer and is, e.g., a SiC or Sapphire substrate or the like. The first and second semiconductor layers 5 and 7 are made of a semiconductor material, preferably of GaN, but could also be of Silicon, strained Silicon, Germanium, SiGe or such as III-V material, III/N material, binary or tertiary alloy like GaN, InGaN, AIGaN and the likes. The first and second semiconductor layers 5 and 7 can be provided over the substrate 3, via an epitaxial growth process or can be otherwise provided over the substrate 3, for example, by a layer transfer and the likes.

According to a variant, substrate 3 could also be a substrate comprising transferred layers, like a GaNOS substrate, corresponding to a sapphire substrate with a transferred GaN layer. The transferred layers could comprise metallic or isolating layers depending on the desired properties, e.g., electric or thermal conductivity, etc. The substrate 3 could also be a template substrate, e.g., a sapphire substrate with a thin GaN layer grown thereon.

In this embodiment, the first semiconductor layer 5 is doped with an n-type impurity and the second semiconductor layer 7 is doped with a p-type impurity. In a variant, the first semiconductor layer 5 can be doped with a p-type impurity and the second semiconductor layer 7 can be doped with an n-type impurity. The interface region 9 between the n-type first and p-type second semiconductor layer 5 and 7 forms a metallurgic junction. In a variant, in a p-n junction diode, the first semiconductor layer 5 is doped with silicon and the second semiconductor layer 7 is doped with magnesium.

The second semiconductor layer 7 includes a plurality of defects and/or dislocations 11a-11d. The defects and/or dislocations 11a-11d in the second semiconductor layer 7 can be due to crystal and/or physical properties mismatch with respect to the material of the first semiconductor layer 5.

In an embodiment of the present invention, a plurality of defects and/or dislocations 11b and 11c arise at a region 3a in the vicinity between the substrate 3 and the first semiconductor layer 5, for example, due to crystal and/or physical properties mismatch between the material of the substrate 3 and the material of the first semiconductor layer 5 and defect 11a may be due to loop dislocation. The defects and/or dislocations 11a-11d continue and/or propagate along the thickness direction of the first semiconductor layer 5 up to the surface of the second semiconductor layer 7. The defects and/or dislocations 11a-11d extend over the interface region 9 and typically up to an exposed surface 13 of the second semiconductor layer 7. The exposed surface 13 typically has a surface defect and/or dislocation density of up to 1×10⁷ cm⁻² for III-N materials such as GaN. For Si or Ge materials or for alloys Si_{1-y}Ge_{y}, where y>0.2, the defect density is less than 1×10⁶ cm⁻². These values depend, however, strongly on the thickness of the layer 7, as will be explained below.

The invention is of interest below a certain dislocation density, which is actually a function of layer thickness. Indeed, depending on the thickness of the layer, the size of the pit formed by etching is more or less important and the entirety of the pits could cover the total surface of the semiconductor, so that one would have to polish the material up to a certain level to find again the semiconductor material.

Typically, when the layer is GaN with 500 nm thickness, the pit after etching has a diameter of about 1 μm. In this case, the material should present a dislocation density below 1 e7/cm2, to have GaN material at the surface 13 to prevent unnecessary polishing into the GaN layer. If the layer has a thickness of 100 nm, the pit will have a dimension of 200 nm and the dislocation density could go up to 1e8/cm2.

The defect density is typically measured by methods known in the art, including, atomic force microscopy, optical microscopy, scanning electron microscopy and transmission electron microscopy. According to the present embodiment, the preferred method for measuring the defect density is by transmission electron microscopy (TEM).

Such defects and/or dislocations 11a-11d hinder the performance of the semiconductor device structure 1, for instance, concerning breakdown voltage and further negatively affects the quality of the exposed surface 13, which has a negative impact on the quality of any further layers provided thereon.

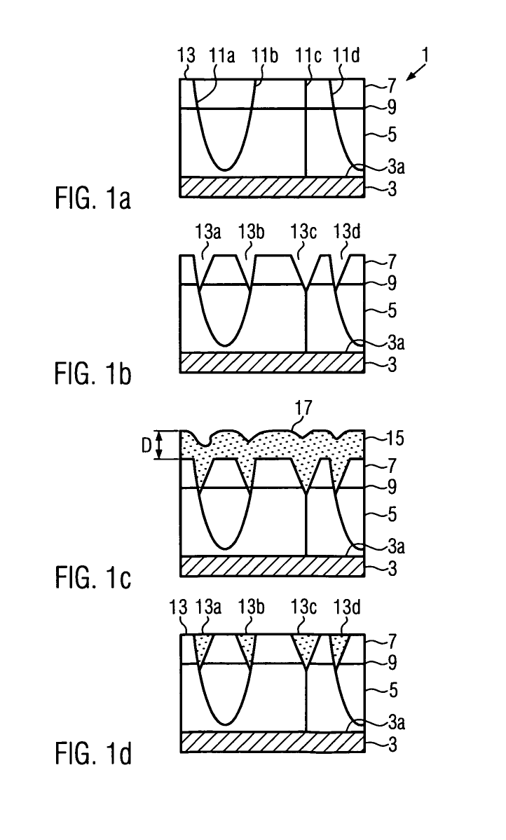

FIGS. 1b-1d illustrate a method, according to a first embodiment of the present invention, which helps to overcome the above-mentioned problems.

FIG. 1b illustrates a step of removing material starting from the exposed surface 13. The material is removed at one or more locations of the defects and/or dislocations 11a-11d. The material can be removed, for example, by a selective or preferential etching. Such an etching creates a plurality of etched regions 13a-13d over the exposed surface 13.

According to the invention, the material removal step is carried out at least until the interface region 9 is exposed or revealed and even beyond such that the region of material removal intersects the interface region 9. With the material removing step, the defects and/or dislocations 11a-11d in the high electric field regions of the semiconductor device structure at the interface 9 are removed. This leads to an improved performance of the semiconductor device, as the breakthrough voltage properties are optimized.

The exposed surface 13, having undergone etching to form the regions 13a-13d, will then be passivated for further device fabrication steps. FIG. 1c illustrates a step of filing the regions 13a-13d at least partially with a dielectric layer or a dielectric material 15. To do so, the dielectric layer 15 is deposited on the exposed surface 13 such that the regions 13a-13d are at least partially filled with the dielectric material 15. The filling of dielectric material can be performed by depositing using any one of chemical vapor deposition (CVD), plasma enhanced chemical vapor deposition (PECVD), low pressure chemical vapor deposition (LPCVD), or by growing, or by otherwise placing dielectric material on the exposed surface 13 of the semiconductor layer 7 so as to occlude the surface openings of the pits and cover any exposed portions of the walls of the pits, but so as those intact portions of the surface away from the pits are exposed. In this embodiment, the dielectric material 15, depending on the application, can be chosen from any one of silicon oxide, silicon nitride and mixtures thereof.

In this embodiment of the present invention, as illustrated in FIG. 1c, the dielectric material 15 completely fills the regions 13a-13d. Furthermore, the dielectric material 15 in this embodiment does not only completely fill the regions 13a-13d but is also provided over the p-type semiconductor layer 7 up to a thickness D. The thickness D can be determined by any known techniques such as optical ellipsometry and the likes. According to the present embodiment, the thickness D is substantially equal to at least the depth of a pit shown in FIG. 1c. The dielectric material 15 filled in the regions 13a-13d extend into the surface of the p-type semiconductor material 7 and intersects the interface region 9. According to variants, the dielectric might only partially fill the regions 13a-13c or deposition is stopped at the surface of the second layer 7.

FIG. 1d illustrates a step of polishing surface 17 of the dielectric material 15. The dielectric material 15 is polished using any conventional techniques such as chemical mechanical polishing (CMP). The dielectric material 15 is polished such that excess dielectric material over the p-type semiconductor layer 7 is removed and the regions 13a-13c remain filled by remaining dielectric materials 15′. The surface of the semiconductor device structure 1 is polished such that the surface comprises regions free of defects and/or dislocations 11a-11d and free of excess dielectric material.

The excess dielectric material relates to those portions of the dielectric material, which are deposited on the exposed surface 13 but are not occluding surface openings of the pits. The excess dielectric material is removed during the polishing step. A surface smoothing process can also be performed on the exposed surface 13. By doing so, the surface can be of high quality and ready for further fabrication steps comprising providing, e.g., by deposition or growth of additional layers over the semiconductor device structure 1.

FIG. 1d illustrates the pn-junction region of the semiconductor device structure 1′, according to the second embodiment of the invention. It comprises the substrate 3, the interface region 9 between the n-type semiconductor layer 5 and the p-type semiconductor layer 7 and an exposed surface 13 of the p-type semiconductor material 7. Pits 13a-13d filled with the dielectric material 15 are provided over the surface 13 at one or more locations where defects and/or dislocations 11a-11d were present, before forming the pits. The one or more pits 13a-13d intersect the interface region 9 and the one or more pits 13a-13d are at least partially filled with the dielectric material 15.

The semiconductor device structure 1′, as illustrated in FIG. 1d, has fewer defects and/or dislocations at the interface between the first and the second layers, when compared to the semiconductor device structure 1, illustrated in FIG. la due to the removal of defects and/or dislocations from the regions 13a-13d that extend through the p-type semiconductor material 7 and further beyond the interface region 9. Further, the semiconductor device structure 1′ has an improved surface quality due to passivation of the surface of the p-type semiconductor material 7 with the dielectric material 15.

The individual features of the various embodiments can be combined independently of each other to reach further variations of the inventive embodiments.

The embodiments of the invention provide the advantage that an improved performance can be obtained from the semiconductor device structure, by removing the defects and/or dislocations from beyond the interface region of the semiconductor device structure. Further, the surface quality of the semiconductor device structure has also been further improved by removing most or all of the defects and/or dislocations. In particular, the breakdown voltage properties can be improved. By passivating the etched regions by providing the dielectric layer and by polishing the excess dielectric material, the surface of the semiconductor device structure has been made ready for further fabrication processes.

1. A method for fabricating a substrate for a semiconductor device comprising an interface region between a first layer and a second layer having different electrical properties and an exposed surface, wherein at least the second layer includes at least one of defects and dislocations, the method comprising the steps of:
a) removing material at one or more locations of the at least one of defects and dislocations, thereby forming pits, wherein the pits intersect the interface region; and
b) passivating the pits.

2. The method according to claim 1, wherein the passivating step includes at least partially filling the pits with a dielectric material.

3. The method according to claim 1, wherein the first layer comprises a semiconductor material including a first impurity and the second layer comprises a semiconductor material including a second impurity different from the first impurity.

4. The method according to claim 1, wherein the step a) comprises a step of etching the exposed surface preferentially at one or more locations of the at least one of defects and dislocations.

5. The method according to claim 1, wherein the dielectric material is chosen from any one of silicon oxide, silicon nitride and mixtures thereof.

6. The method according to claim 1, wherein the dielectric material completely fills the regions from which the material is removed in step a).

7. The method according to claim 1, further comprising a step of polishing the surface of the semiconductor device after step b), wherein the surface of the substrate for the semiconductor device is polished until the surface of the second layer is exposed.

8. The method according to claim 1, wherein the semiconductor device comprises at least one of a transistor, a diode, and a photovoltaic device.

9. A substrate for a semiconductor device, comprising an interface region between a first semiconductor layer and a second semiconductor layer having different electrical properties, wherein pits extend through the second layer and at least partially into the first layer so as to cross the interface region, wherein the pits are at least partially filled with a dielectric material.

10. The substrate for a semiconductor device according to claim 9, wherein the first layer comprises a semiconductor material including a first impurity and the second layer comprises a semiconductor material including a second impurity different from the first impurity.

11. The substrate for a semiconductor device according to claim 10, wherein the semiconductor material is a III/N material, the first impurity is silicon and the second impurity is magnesium.

12. The substrate for a semiconductor device according to claim 9, wherein the dielectric material is selected from the group consisting of silicon oxide, silicon nitride and mixtures thereof.

13. The substrate for a semiconductor device according to claim 9, wherein the dielectric material completely fills the one or more regions.

14. The substrate for a semiconductor device according to claim 9, wherein the pits filled with dielectric material are arranged on top of at least one of dislocations and defects in the first layer.

15. A power semiconductor device including the substrate according to claim 9.

16. The method according to claim 2, wherein the first layer comprises a semiconductor material including a first impurity and the second layer comprises a semiconductor material including a second impurity different from the first impurity.

17. The method according to claim 2, wherein the step a) comprises a step of etching the exposed surface preferentially at one or more locations of the at least one of defects and dislocations.

18. The method according to claim 3, wherein the step a) comprises a step of etching the exposed surface preferentially at one or more locations of the at least one of defects and dislocations.

19. The substrate for a semiconductor device according to claim 11, wherein the dielectric material is selected from the group consisting of silicon oxide, silicon nitride and mixtures thereof.

20. The substrate for a semiconductor device according to claim 19, wherein the pits filled with dielectric material are arranged on top of at least one of dislocations and defects in the first layer.
